(19) United States
(12) Patent Application Publication
(10) Pub. No.: US 2026/0331795 A1
(43) Pub. Date: Oct. 22, 2026

(54) PRESS-FIT CONNECTOR WITH EYE OF NEEDLE PROFILE

(71) Applicant: Cisco Technology, Inc., San Jose, CA (US)

(72) Inventors: Zhenxuan CHEN, Shanghai (CN); Jing LI, Shanghai (CN)

(21) Appl. No.: 19/185,140

(22) Filed: Apr. 21, 2025

(51) Int. Cl. H01R 12/58; H05K 1/11

(52) U.S. Cl. CPC H01R 12/585; H05K 1/115; H05K 2201/0959

(57) ABSTRACT

A press-fit connector with an eye of needle profile is provided. In one aspect, a press-fit connector includes a base, a tip, and a pin body. The pin body extends longitudinally between the base and the tip. The pin body has a first arm and a second arm that are resiliently deformable and joined at opposite ends. The first arm and the second arm each include an outer sidewall that has an outwardly curved arc defining a cutout. Further, the pin body has an inner sidewall defining an opening between the first arm and the second arm. The inner sidewall has opposing outwardly curved arcs that are connected at their respective upper ends by an upper inwardly curved arc of the inner sidewall and at their respective lower ends by a lower inwardly curved arc of the inner sidewall.

### TECHNICAL FIELD

The present disclosure generally relates to electronic components, and more specifically, to press-fit connectors.

### BACKGROUND

Various types of connections may be used to connect circuit components to a circuit board. One type of connection is a press-fit connection made by pressing a press-fit pin into a circuit board through a hole in the circuit board. The press-fit pin is designed to be inserted into a plated through hole in the circuit board to provide an electro-mechanical connection.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 is a perspective view of a press-fit connector according to one or more aspects of the present disclosure.

FIG. 2 is a front view of the press-fit connector of FIG. 1.

FIG. 3 is another front view of the press-fit connector of FIG. 1.

FIG. 4 is a cross-sectional view of an apparatus having a printed circuit board, a plated through hole extending through the printed circuit board, and the press-fit connector of FIG. 1 received within the plated through hole.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

In one aspect, a press-fit connector is provided. The press-fit connector includes a base, a tip, and a pin body. The pin body extends longitudinally between the base and the tip. The pin body has a first arm and a second arm that are resiliently deformable and joined at opposite ends. The first arm and the second arm each include an outer sidewall that has an outwardly curved arc defining a cutout. Further, the pin body has an inner sidewall defining an opening between the first arm and the second arm. The inner sidewall has opposing outwardly curved arcs that are connected at their respective upper ends by an upper inwardly curved arc of the inner sidewall and at their respective lower ends by a lower inwardly curved arc of the inner sidewall.

In another aspect, a press-fit connector is provided. The press-fit connector includes a pin body defining an opening having a first radiused end and a second radiused end that oppose one another and are connected by a section of the opening that gradually narrows from the first radiused end to a bisecting plane of the opening and that gradually narrows from the second radiused end to the bisecting plane.

In yet another aspect, an apparatus is provided. The apparatus includes a printed circuit board (PCB), a plated through hole (PTH) extending through the PCB, and a press-fit connector received with the PTH. The press-fit connector includes a base, a tip, and a pin body. The pin body extends longitudinally between the base and the tip. The pin body includes a first arm and a second arm that are resiliently deformed by the PTH and joined at opposite ends. The first arm and the second arm each include an outer sidewall that has an outwardly curved arc defining a cutout such that at least a portion of the outwardly curved arc does not contact the PTH. The pin body has an inner sidewall defining an opening between the first arm and the second arm. The inner sidewall has opposing outwardly curved arcs that are connected at their respective upper ends by an upper inwardly curved arc of the inner sidewall and at their respective lower ends by a lower inwardly curved arc of the inner sidewall.

In yet a further aspect, a press-fit connector is provided. The press-fit connector includes a pin body having a first arm and a second arm that are resiliently deformable and joined at opposite ends. The first arm has a first outer sidewall that has a first outwardly curved arc arranged between and connected to first inwardly curved arcs. The first outwardly curved arc defines a first cutout. The second arm has a second outer sidewall that has a second outwardly curved arc arranged between and connected to second inwardly curved arcs. The second outwardly curved arc defines a second cutout.

### Example Embodiments

Disclosed herein is a press-fit connector defining an opening with an eye of needle (EON) profile. The press-fit connector of the present disclosure can include features for lowering the insertion force of the press-fit connector during press-fit insertion, e.g., into a plated through hole (PTH) of a printed circuit board (PCB) so as to electrically connect components on opposing sides of the PCB. Also, the press-fit connector of the present disclosure can include features for enhancing the retention force for securing a tighter contact with the PTH. In addition, the press-fit connector of the present disclosure can compensate for the relatively large tolerance limit of the PTH.

In at least one aspect, a press-fit connector with an EON profile is provided. The press-fit connector can include a base, a tip, and a pin body. The pin body can extend longitudinally between the base and the tip. The pin body can have a first arm and a second arm that are resiliently deformable and joined at opposite ends. The first arm can include a first outer sidewall that has a first outwardly curved arc defining a first cutout. The first cutout effectively “interrupts” or changes the curvature of an inwardly curved shape of the first outer sidewall, e.g., with an outwardly curved section. Similarly, the second arm can include a second outer sidewall that has a second outwardly curved arc defining a second cutout. The second cutout effectively “interrupts” or changes the curvature of an inwardly curved shape of the second outer sidewall, e.g., with an outwardly curved section. Advantageously, the first cutout and the second cutout can relieve stress when the press-fit connector engages a PTH and material of the pin body squeezes upward. The first and second cutouts can reduce the contact area that the press-fit connector has with the PTH, and thus, the insertion force of the press-fit connector can be reduced.

Further, the pin body can have an inner sidewall defining an opening between the first arm and the second arm. The inner sidewall can have opposing outwardly curved arcs that are connected at their respective upper ends by an upper inwardly curved arc of the inner sidewall and at their respective lower ends by a lower inwardly curved arc of the inner sidewall. Stated another way, the opening can have a first radiused end and a second radiused end that oppose one another and are connected by a section of the opening that gradually narrows from the first radiused end to a bisecting plane of the opening and that gradually narrows from the second radiused end to the bisecting plane. In this way, the opening can have a profile that includes opposing larger-width rounded ends with a narrow midsection. Advantageously, the larger-width rounded ends and overall profile of the opening can provide more space to relieve stresses within the press-fit connector so that, when material is squeezed upward in the press-fit process, more stress is accumulated at the upper end of the pin body. Thus, the retention force of the press-fit connector can be enhanced.

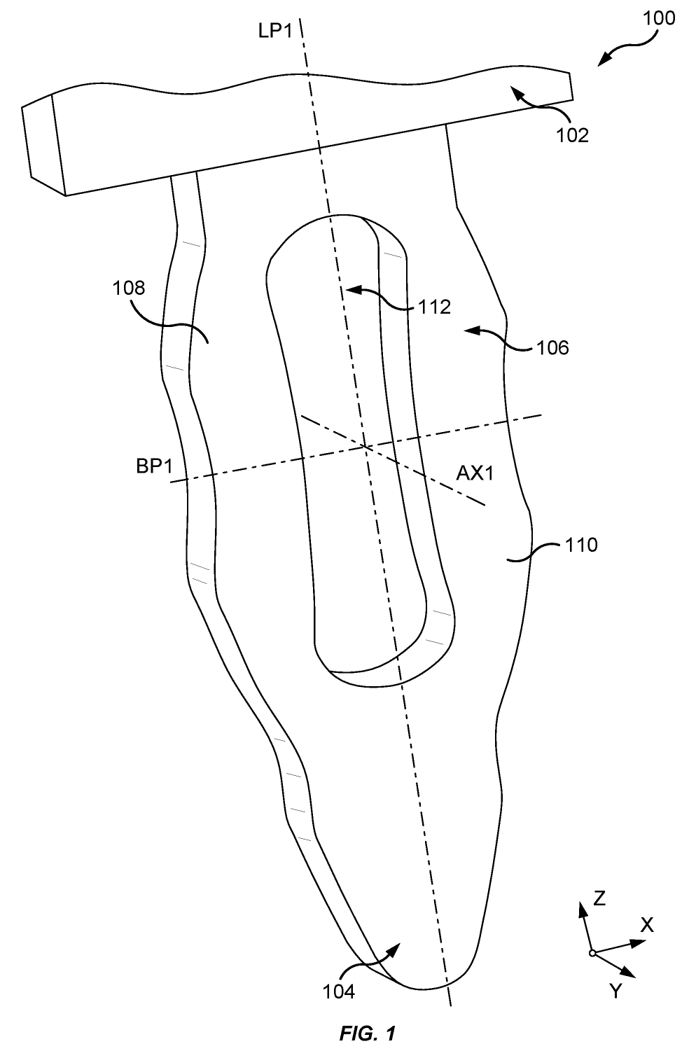

Turning now to the drawings, FIG. 1 is a perspective view of a press-fit connector 100 according to one or more aspects of the present disclosure. The press-fit connector 100 of FIG. 1 is arranged to be press fit into a plated through hole (PTH) of a printed circuit board (PCB), e.g., to electrically connect components on opposing sides of the PCB. For reference, the press-fit connector 100 defines an X-direction, a Y-direction, and a Z-direction, which are mutually perpendicular to one another. In one or more examples, the X-direction can be a lateral direction, the Y-direction can be a transverse direction, and the Z-direction can be a longitudinal direction (or vertical direction). The press-fit connector 100 has a width extending along the X-direction, a thickness along the Y-direction, and a length along the Z-direction. Also, the press-fit connector 100 can define a longitudinal plane LP1, which bisects the press-fit connector 100 into a first side and a second side. In at least one example, the press-fit connector 100 can be symmetric with respect to the longitudinal plane LP1. As used herein, the term “inner” or “innermost” and “outer” or “outermost”, or like terms, are referred to with respect to the longitudinal plane LP1.

As depicted in FIG. 1, the press-fit connector 100 has a base 102, a tip 104, and a pin body 106 extending longitudinally between the base 102 and the tip 104. The pin body 106 has a first arm 108 and a second arm 110 that are resiliently deformable and joined at opposite ends. The pin body 106 defines an opening 112. The opening 112 is defined by the pin body 106 between the first arm 108 and the second arm 110. For the depicted example of FIG. 1, the opening 112 has an eye of needle (EON) shape. The opening 112 can define a center axis AX1 as well as a bisecting plane BP1. The center axis AX1 can extend along the Y-direction. The bisecting plane BP1 can be perpendicular to the Z-direction. In this regard, the bisecting plane BP1 can extend in an XY-plane. In one or more examples, the opening 112 is symmetrical with respect to the bisecting plane BP1.

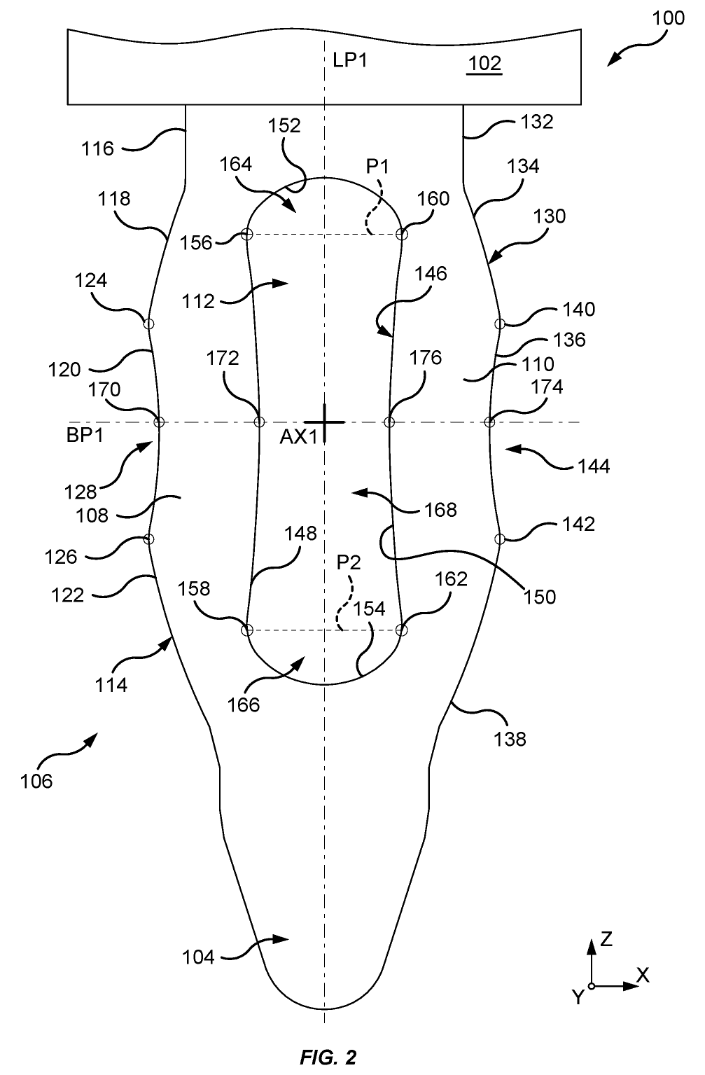

With reference now to FIGS. 1 and 2, FIG. 2 is a front view of the press-fit connector 100. As depicted, the first arm 108 has a first outer sidewall 114 that has a first connector segment 116, a first upper inwardly curved arc 118, a first outwardly curved arc 120, and a first lower inwardly curved arc 122. The first connector segment 116 is connected to the base 102 at its upper end and with the first upper inwardly curved arc 118 at its lower end. The first upper inwardly curved arc 118 is concave with respect to the center axis AX1. The first upper inwardly curved arc 118 is connected with the first connector segment 116 at its upper end and with the first outwardly curved arc 120 at its lower end, or rather, at a first upper outermost point 124. The first outwardly curved arc 120 is convex with respect to the center axis AX1. The first outwardly curved arc 120 is connected with the first upper inwardly curved arc 118 at its upper end and with the first lower inwardly curved arc 122 at its lower end, or rather, at a first lower outermost point 126. The first lower inwardly curved arc 122 extends downward along the Z-direction toward the tip 104. The first lower inwardly curved arc 122 is concave with respect to the center axis AX1.

In this example, the first outwardly curved arc 120 defines a first cutout 128. The first cutout 128 effectively interrupts the inwardly curved shape of the first outer sidewall 114, e.g., with an outwardly curved section. Advantageously, the first cutout 128 can relieve stress when the press-fit connector 100 touches a PTH and can facilitate the squeezing of material upward along the Z-direction. In this way, the insertion force of the press-fit connector 100 can be reduced. Indeed, there is less area that the press-fit connector 100 engages with the PTH.

The second arm 110 has a second outer sidewall 130 that has a second connector segment 132, a second upper inwardly curved arc 134, a second outwardly curved arc 136, and a second lower inwardly curved arc 138. The second connector segment 132 is connected to the base 102 at its upper end and with the second upper inwardly curved arc 134 at its lower end. The second upper inwardly curved arc 134 is concave with respect to the center axis AX1. The second upper inwardly curved arc 134 is connected with the second connector segment 132 at its upper end and with the second outwardly curved arc 136 at its lower end, or rather, at a second upper outermost point 140. The second outwardly curved arc 136 is convex with respect to the center axis AX1. The second outwardly curved arc 136 is connected with the second upper inwardly curved arc 134 at its upper end and with the second lower inwardly curved arc 138 at its lower end, or rather, at a second lower outermost point 142. The second lower inwardly curved arc 138 extends downward along the Z-direction toward the tip 104. The second lower inwardly curved arc 138 is concave with respect to the center axis AX1.

In this example, the second outwardly curved arc 136 defines a second cutout 144. The second cutout 144 effectively interrupts the inwardly curved shape of the second outer sidewall 130, e.g., with an outwardly curved section. Advantageously, the second cutout 144 can relieve stress when the press-fit connector 100 touches a PTH and can facilitate the squeezing of material upward along the Z-direction. In this way, the insertion force of the press-fit connector 100 can be reduced. Indeed, there is less area that the press-fit connector 100 engages with the PTH.

As further shown in FIGS. 1 and 2, the pin body 106 has an inner sidewall 146 that defines the opening 112 between the first arm 108 and the second arm 110. The inner sidewall 146 has opposing outwardly curved arcs, including a first outwardly curved arc 148 and a second outwardly curved arc 150. The first outwardly curved arc 148 is convex with respect to the center axis AX1. Similarly, the second outwardly curved arc 150 is convex with respect to the center axis AX1. The first and second outwardly curved arcs 148, 150 are connected at their respective upper ends by an upper inwardly curved arc 152 of the inner sidewall 146 and at their respective lower ends by a lower inwardly curved arc 154 of the inner sidewall 146. For instance, for the first arm 108, the first outwardly curved arc 148 of the inner sidewall 146 can extend between an upper inflection point 156 and a lower inflection point 158. Accordingly, the first outwardly curved arc 148 of the inner sidewall 146 can be connected to the upper inwardly curved arc 152 at the upper inflection point 156 and can be connected to the lower inwardly curved arc 154 at the lower inflection point 158. For the second arm 110, the second outwardly curved arc 150 of the inner sidewall 146 extends between an upper inflection point 160 and a lower inflection point 162. Thus, the second outwardly curved arc 150 of the inner sidewall 146 can be connected to the upper inwardly curved arc 152 at the upper inflection point 160 and can be connected to the lower inwardly curved arc 154 at the lower inflection point 162.

Accordingly, the opening 112 has a first radiused end 164 and a second radiused end 166 that oppose one another and are connected by a section 168 of the opening 112 that gradually narrows from the first radiused end 164 to the bisecting plane BP1 of the opening 112 and that gradually narrows from the second radiused end 166 to the bisecting plane BP1. Thus, the opening 112 has a profile that includes opposing larger-width rounded ends with a narrow midsection. In this manner, the opening 112 can have an hour-glass like profile. Advantageously, the larger-width rounded ends and overall profile of the opening 112 can provide more space to relieve stresses within the press-fit connector 100 so that when material is squeezed upward in the press-fit process, more stress is accumulated at the upper end of the pin body 106, and thus, the retention force of the press-fit connector 100 can be enhanced.

In at least one example, the section 168 of the opening 112 arranged between and connecting the first radiused end 164 and the second radiused end 166 can extend between a first plane P1 and a second plane P2. As shown in FIG. 2, the first plane P1 can include or is coplanar with the upper inflection points 156, 160 and the second plane P2 can include or is coplanar with the lower inflection points 158, 162. The first plane P1 and the second plane P2 can be parallel to one another and both perpendicular to the Z-direction.

In one or more examples, for the first arm 108, an innermost point 170 of the first outwardly curved arc 120 of the first outer sidewall 114 and an innermost point 172 of the first outwardly curved arc 148 of the inner sidewall 146 are aligned longitudinally with the center axis AX1 of the opening 112. For the second arm 110, an innermost point 174 of the second outwardly curved arc 136 of the second outer sidewall 130 and an innermost point 176 of the second outwardly curved arc 150 of the inner sidewall 146 are aligned longitudinally with the center axis AX1 of the opening 112. In at least one example, the innermost point 172 of the first outwardly curved arc 148 and the innermost point 176 of the second outwardly curved arc 150 can be aligned with the bisecting plane BP1 of the opening 112 along the Z-direction, which can be a longitudinal direction.

In one or more examples, for the first arm 108, the first outwardly curved arc 120 of the first outer sidewall 114 extends between the upper outermost point 124 and the lower outermost point 126, e.g., along the Z-direction. The upper outermost point 124 and the lower outermost point 126 can be aligned with one another, e.g., along an axis extending along the X-direction. Further, for the second arm 110, the second outwardly curved arc 136 of the second outer sidewall 130 extends between the second upper outermost point 140 and the second lower outermost point 142, e.g., along the Z-direction. The second upper outermost point 140 and the second lower outermost point 142 can be aligned with one another, e.g., along an axis extending along the X-direction.

In at least one example, for the first arm 108, the innermost point 170 of the first outwardly curved arc 120 is positioned between the upper outermost point 124 and the lower outermost point 126 of the first outer sidewall 114. The innermost point 170 can be disposed closer to the center axis AX1 of the opening 112 than are the first upper and lower outermost points 124, 126. In addition, for the second arm 110, the innermost point 174 of the second outwardly curved arc 136 is positioned between the second upper outermost point 140 and the second lower outermost point 142 along the second outer sidewall 130. The innermost point 174 can be disposed closer to the center axis AX1 than are the second upper and lower outermost points 140, 142.

In one or more further examples, the innermost point 172 of the first outwardly curved arc 148 of the inner sidewall 146 and the innermost point 176 of the second outwardly curved arc 150 of the inner sidewall 146 can be longitudinally aligned with the center axis AX1 of the opening 112.

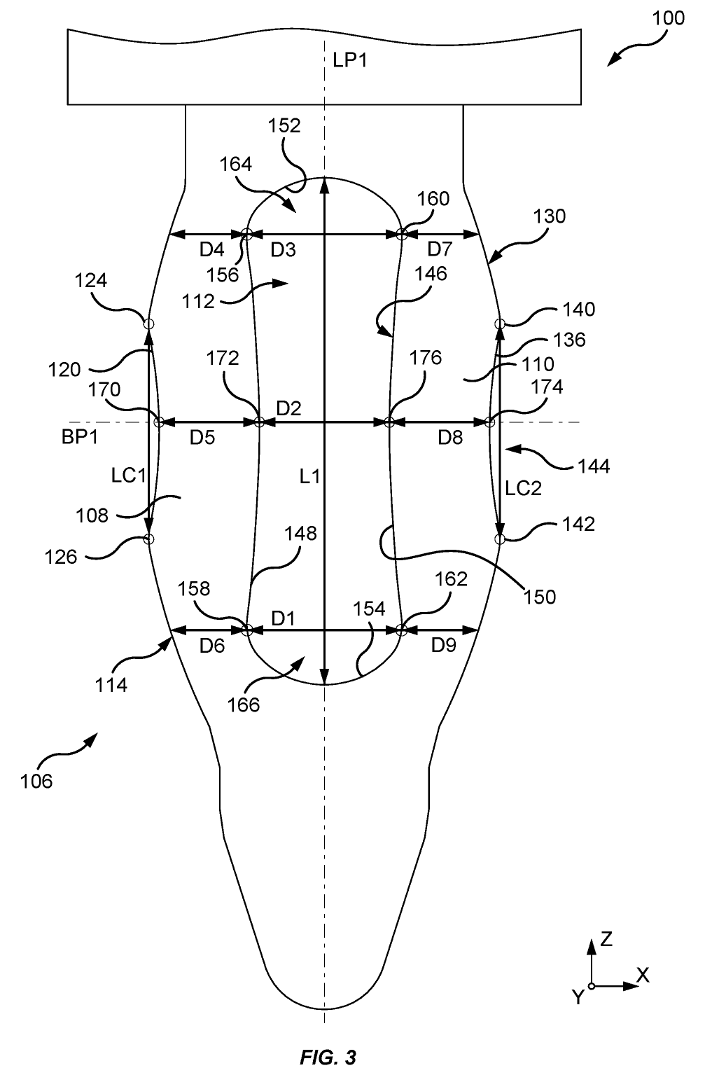

FIG. 3 is another front view of the press-fit connector 100. As depicted, in one or more examples, a distance D1 between the lower inflection points 158, 162 is greater than a distance D2 between the innermost points 172, 176 of the first and second outwardly curved arcs 148, 150 of the inner sidewall 146. Also, a distance D3 between the upper inflection points 156, 160 is greater than the distance between the innermost points 172, 176 of the first and second outwardly curved arcs 148, 150 of the inner sidewall 146. In this way, the opening 112 is wider at its ends than at its center. In at least one example, the distance D1 can be equal to the distance D3.

In addition, in at least one example, the distance D2 between the innermost point 172 of the first outwardly curved arc 148 of the inner sidewall 146 and the innermost point 176 of the second outwardly curved arc 150 of the inner sidewall 146 is a shortest distance between the opposing first and second outwardly curved arcs 148, 150 of the inner sidewall 146.

Further, in one or more examples, a distance D4 between the upper inflection point 156 of the inner sidewall 146 and the first outer sidewall 114 of the first arm 108 is less than a distance D5 between the innermost point 172 of the first outwardly curved arc 148 of the inner sidewall 146 and the innermost point 170 of the first outwardly curved arc 120 of the first outer sidewall 114 of the first arm 108. Also, a distance D6 between the lower inflection point 158 of the inner sidewall 146 and the first outer sidewall 114 of the first arm 108 is less than the distance D5 between the innermost point 172 of the first outwardly curved arc 148 of the inner sidewall 146 and the innermost point 170 of the first outwardly curved arc 120 of the first outer sidewall 114 of the first arm 108. In at least one example, the distance D4 can be equal to the distance D5.

In one or more further examples, a distance D7 between the upper inflection point 160 of the inner sidewall 146 and the second outer sidewall 130 of the second arm 110 is less than a distance D8 between the innermost point 176 of the second outwardly curved arc 150 of the inner sidewall 146 and the innermost point 174 of the second outwardly curved arc 136 of the second outer sidewall 130 of the second arm 110. Also, a distance D9 between the lower inflection point 162 of the inner sidewall 146 and the second outer sidewall 130 of the second arm 110 is less than the distance D8 between the innermost point 176 of the second outwardly curved arc 150 of the inner sidewall 146 and the innermost point 174 of the second outwardly curved arc 136 of the second outer sidewall 130 of the second arm 110. In at least one example, the distance D7 can be equal to the distance D9. In at least one example, the distances D4, D6, D7, D9 can be equal to one another. In at least one example, the distances D5, D8 can be equal to one another.

Referring still to FIG. 3, in one or more examples, the opening 112 has a longitudinal length L1 and the first outwardly curved arc 120 of the first outer sidewall 114 of the first arm 108 has a longitudinal chord length LC1. In such examples, a ratio of the longitudinal chord length LC1 of the first outwardly curved arc 120 to the longitudinal length L1 of the opening 112 can be between 2:5 and 1:2, including the endpoints. Further, in one or more examples, the second outwardly curved arc 136 of the second outer sidewall 130 of the second arm 110 has a longitudinal chord length LC2. In such examples, a ratio of the longitudinal chord length LC2 of the second outwardly curved arc 136 to the longitudinal length L1 of the opening 112 can be between 2:5 and 1:2, including the endpoints. In at least one example, the longitudinal chord length LC1 of the first outwardly curved arc 120 can equal the longitudinal chord length LC2 of the second outwardly curved arc 136.

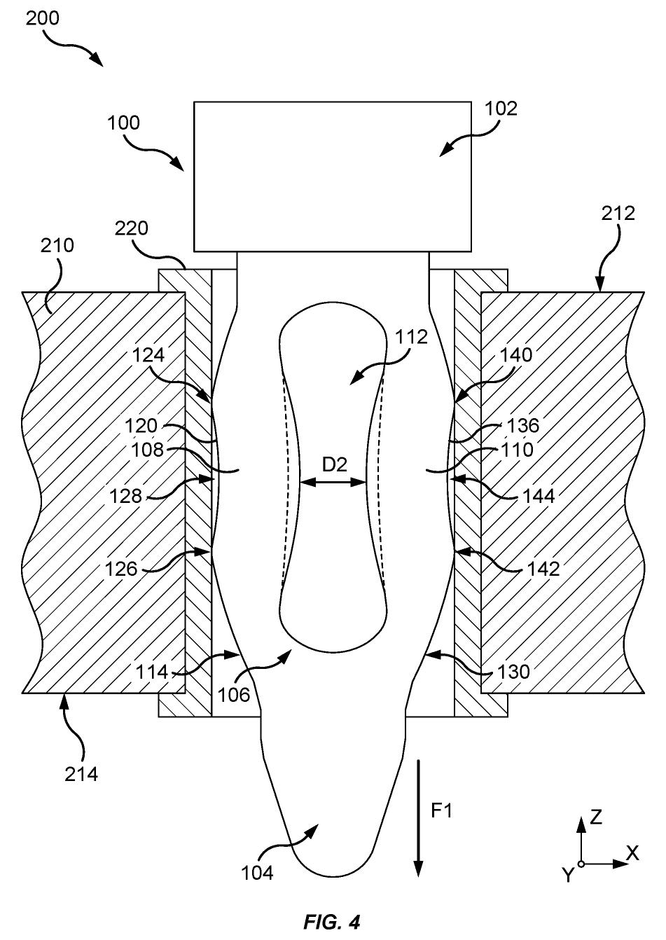

FIG. 4 is a cross-sectional view of an apparatus 200 having a PCB 210, a PTH 220 extending through the PCB 210, and the press-fit connector 100 of FIG. 1 press fit within the PTH 220.

As depicted, the press-fit connector 100 can be press fit into the PTH 220 by application of a force F1, which is applied downward along the Z-direction in this example. The base 102 can be held as the press-fit connector 100 is driven downward along the Z-direction through the PTH 220. The base 102 can remain on a first side 212 of the PCB 210. The tip 104, being of smaller width and thickness dimensions than the diameter of the through hole provided by the PTH 220, can travel through the PTH 220 without engaging the PTH 220 and can be arranged on a second side 214 of the PCB 210. Accordingly, the press-fit connector 100 can extend through the PTH 220, as well as the PCB 210.

As the press-fit connector 100 is press fit into the PTH 220, the pin body 106 engages the PTH 220. As illustrated in FIG. 4, the first arm 108 and the second arm 110 are resiliently deformed by the PTH 220. The first arm 108 engages the PTH 220 generally at the first upper and lower outermost points 124, 126, while the second arm 110 engages the PTH 220 generally at the second upper and lower outermost points 140, 142. The first and second cutoffs 128, 144 defined by the first and second outer sidewalls 114, 130 of the pin body 106 can relieve stress when the press-fit connector 100 engages the PTH 220. The first and second cutoffs 128, 144 can facilitate the material of the pin body 106 squeezing upward along the Z-direction, which can lower the insertion force because there is reduced touching/contact area with the PTH 220. As depicted in FIG. 4, the first outwardly curved arc 120 of the first outer sidewall 114 and the second outwardly curved arc 136 of the second outer sidewall 130 are mostly not in contact with the PTH 220. In this example, the first outwardly curved arc 120 and the second outwardly curved arc 136 are only in contact with the PTH 220 immediately proximate the outermost points 124, 126, 140, 142. In this manner, at least a portion of the first outwardly curved arc 120 does not contact the PTH 220 and at least a portion of the second outwardly curved arc 136 does not contact the PTH 220.

As the material of the pin body 106 squeezes upward, the distance D2 can become shorter, as represented by the phantom lines showing the non-loaded profile of the opening 112 and the solid lines showing the loaded profile of the opening 112 when the press-fit connector 100 is press fit into the PTH 220. The profile of the opening 112, with the relatively large-width radiused ends and narrower mid-section, can relieve stress in the pin body 106 when the material is being squeezed upward in the press-fit process. In this way, more stress is accumulated at the upper end of the pin body 106, which can enhance the retention force of the press-fit connector 100.

To summarize, the press-fit connector of the present disclosure can allow a lower insertion force and a bigger retention force compared to other press-fit connectors. In at least one aspect, the press-fit connector of the present disclosure can provide a retention force to insertion force ratio, or locking ratio, of at least being greater than 0.7. Moreover, the press-fit connector of the present disclosure can compensate for the relatively large tolerance of the PTH, thus ensuring low contact resistance and small deformation of the PTH.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. A press-fit connector, comprising:
a base;
a tip; and
a pin body extending longitudinally between the base and the tip, wherein the pin body comprises a first arm and a second arm that are resiliently deformable and joined at opposite ends, wherein the first arm and the second arm each include an outer sidewall that has an outwardly curved arc defining a cutout,
wherein the pin body has an inner sidewall defining an opening between the first arm and the second arm, the inner sidewall having opposing outwardly curved arcs that are connected at their respective upper ends by an upper inwardly curved arc of the inner sidewall and at their respective lower ends by a lower inwardly curved arc of the inner sidewall.

2. The press-fit connector of claim 1, wherein:
for the first arm, an innermost point of the outwardly curved arc of the outer sidewall and an innermost point of the outwardly curved arc of the inner sidewall are aligned longitudinally with a center axis of the opening, and
for the second arm, an innermost point of the outwardly curved arc of the outer sidewall and an innermost point of the outwardly curved arc of the inner sidewall are aligned longitudinally with the center axis of the opening.

3. The press-fit connector of claim 1, wherein:
for the first arm, the outwardly curved arc of the outer sidewall extends between an upper outermost point and a lower outermost point along the outer sidewall, and
for the second arm, the outwardly curved arc of the outer sidewall extends between an upper outermost point and a lower outermost point along the outer sidewall.

4. The press-fit connector of claim 3, wherein:
for the first arm, an innermost point of the outwardly curved arc is positioned between the upper outermost point and the lower outermost point of the outer sidewall, the innermost point being disposed closer to a center axis of the opening than are the upper and lower outermost points, and
for the second arm, an innermost point of the outwardly curved arc is positioned between the upper outermost point and the lower outermost point along the outer sidewall, the innermost point being disposed closer to the center axis than are the upper and lower outermost points.

5. The press-fit connector of claim 1, wherein the opposing outwardly curved arcs of the inner sidewall include a first outwardly curved arc and a second outwardly curved arc that opposes the first outwardly curved arc, and wherein an innermost point of the first outwardly curved arc of the inner sidewall and an innermost point of the second outwardly curved arc of the inner sidewall are longitudinally aligned with a center axis of the opening.

6. The press-fit connector of claim 5, wherein:
for the first arm, the outwardly curved arc of the inner sidewall extends between an upper inflection point and a lower inflection point, the outwardly curved arc of the inner sidewall being connected to the upper inwardly curved arc at the upper inflection point and being connected to the lower inwardly curved arc at the lower inflection point, and
for the second arm, the outwardly curved arc of the inner sidewall extends between an upper inflection point and a lower inflection point, the outwardly curved arc of the inner sidewall being connected to the upper inwardly curved arc at the upper inflection point and being connected to the lower inwardly curved arc at the lower inflection point.

7. The press-fit connector of claim 6, wherein:
a distance between the lower inflection points is greater than a distance between the innermost points of the first and second outwardly curved arcs of the inner sidewall, and
a distance between the upper inflection points is greater than a distance between the innermost points of the first and second outwardly curved arcs of the inner sidewall.

8. The press-fit connector of claim 6, wherein:
a distance between the lower inflection point of the inner sidewall and the outer sidewall of the first arm is less than a distance between an innermost point of the outwardly curved arc of the inner sidewall and the innermost point of the outwardly curved arc of the outer sidewall of the first arm.

9. The press-fit connector of claim 6, wherein:
a distance between an innermost point of the outwardly curved arc of the inner sidewall and an innermost point of the outwardly curved arc of the inner sidewall is a shortest distance between the opposing outwardly curved arcs of the inner sidewall.

10. The press-fit connector of claim 1, wherein the opening has a longitudinal length and the outwardly curved arc of the outer sidewall of the first arm has a longitudinal chord length, and wherein a ratio of the longitudinal chord length of the outwardly curved arc to the longitudinal length of the opening is between 2:5 and 1:2.

11. A press-fit connector, comprising:
a pin body defining an opening having a first radiused end and a second radiused end that oppose one another and are connected by a section of the opening that gradually narrows from the first radiused end to a bisecting plane of the opening and that gradually narrows from the second radiused end to the bisecting plane.

12. The press-fit connector of claim 11, wherein the pin body has a first arm and a second arm that are resiliently deformable and joined at opposite ends, wherein the first arm includes a first outer sidewall that has a first outwardly curved arc defining a first cutout and the second arm includes a second outer sidewall that has a second outwardly curved arc defining a second cutout.

13. The press-fit connector of claim 12, wherein the opening is defined between the first arm and the second arm.

14. The press-fit connector of claim 12, wherein an innermost point of the first outwardly curved arc and an innermost point of the second outwardly curved arc are aligned with the bisecting plane of the opening along a longitudinal direction.

15. The press-fit connector of claim 11, wherein the opening is symmetrical with respect to the bisecting plane.

16. An apparatus, comprising:
a printed circuit board (PCB);
a plated through hole (PTH) extending through the PCB; and
a press-fit connector received with the PTH, the press-fit connector comprising:
a base;
a tip; and
a pin body extending longitudinally between the base and the tip, wherein the pin body comprises a first arm and a second arm that are resiliently deformed by the PTH and joined at opposite ends, wherein the first arm and the second arm each include an outer sidewall that has an outwardly curved arc defining a cutout such that at least a portion of the outwardly curved arc does not contact the PTH,
wherein the pin body has an inner sidewall defining an opening between the first arm and the second arm, the inner sidewall having opposing outwardly curved arcs that are connected at their respective upper ends by an upper inwardly curved arc of the inner sidewall and at their respective lower ends by a lower inwardly curved arc of the inner sidewall.

17. The apparatus of claim 16, wherein:
for the first arm, an innermost point of the outwardly curved arc of the outer sidewall and an innermost point of the outwardly curved arc of the outer sidewall are aligned longitudinally with a center axis of the opening, and
for the second arm, an innermost point of the outwardly curved arc of the outer sidewall and an innermost point of the outwardly curved arc of the outer sidewall are aligned longitudinally with the center axis of the opening.

18. The apparatus of claim 16, wherein:
for the first arm, the outwardly curved arc of the outer sidewall extends between an upper outermost point and a lower outermost point along the outer sidewall, and
for the second arm, the outwardly curved arc of the outer sidewall extends between an upper outermost point and a lower outermost point along the outer sidewall.

19. The apparatus of claim 16, wherein the opposing outwardly curved arcs of the inner sidewall include a first outwardly curved arc and a second outwardly curved arc that opposes the first outwardly curved arc, and wherein an innermost point of the first outwardly curved arc of the inner sidewall and an innermost point of the second outwardly curved arc of the inner sidewall are longitudinally aligned with a center axis of the opening.

20. The apparatus of claim 19, wherein:
for the first arm, the outwardly curved arc of the inner sidewall extends between an upper inflection point and a lower inflection point, the outwardly curved arc of the inner sidewall being connected to the upper inwardly curved arc at the upper inflection point and being connected to the lower inwardly curved arc at the lower inflection point, and
for the second arm, the outwardly curved arc of the inner sidewall extends between an upper inflection point and a lower inflection point, the outwardly curved arc of the inner sidewall being connected to the upper inwardly curved arc at the upper inflection point and being connected to the lower inwardly curved arc at the lower inflection point, and wherein:
a distance between the lower inflection points is greater than a distance between the innermost points of the first and second outwardly curved arcs of the inner sidewall, and
a distance between the upper inflection points is greater than a distance between the innermost points of the first and second outwardly curved arcs of the inner sidewall.
